(19) United States
(12) Patent Application Publication
(10) Pub. No.: US 2026/0005029 A1
(43) Pub. Date: Jan. 1, 2026

(54) COMPOSITION, METHOD OF TREATING METAL-CONTAINING LAYER BY USING THE SAME, AND METHOD OF MANUFACTURING SEMICONDUCTOR DEVICE BY USING THE SAME

(71) Applicant: Samsung Electronics Co., Ltd., Suwon-si (KR)

(72) Inventors: Cheol HAM, Suwon-si (KR); Giho KO, Suwon-si (KR); Sungmin KIM, Suwon-si (KR); Youngchan KIM, Suwon-si (KR); Jina KIM, Suwon-si (KR); Wonsik YOON, Suwon-si (KR); Minhyung CHO, Suwon-si (KR); Donghoon HA, Suwon-si (KR); Kyuyoung HWANG, Suwon-si (KR)

(73) Assignee: Samsung Electronics Co., Ltd., Suwon-si (KR)

(21) Appl. No.: 19/020,232

(22) Filed: Jan. 14, 2025

(30) Foreign Application Priority Data
Jun. 26, 2024 (KR) 10-2024-0083740

(51) Int. Cl. H01L 21/306; C23F 1/34; H01L 21/308

(52) U.S. Cl. CPC H01L 21/30604; C23F 1/34; H01L 21/3085

(57) ABSTRACT

Provided are a composition, a method of treating a metal-containing layer by using the same, and a method of manufacturing a semiconductor device by using the same, the composition including an oxidizer, an ammonium-based buffer, and an etching controller, wherein the etching controller includes a compound represented by Formula 1.

### CROSS-REFERENCE TO RELATED APPLICATION

This application is based on and claims priority under 35 U.S.C. § 119 to Korean Patent Application No. 10-2024-0083740, filed on Jun. 26, 2024, in the Korean Intellectual Property Office, the disclosure of which is incorporated by reference herein in its entirety.

### BACKGROUND

### 1. Field

The disclosure relates to a composition, a method of treating a metal-containing layer by using the same, and a method of manufacturing a semiconductor device by using the same.

### 2. Description of the Related Art

To meet the consumer demands for improved performance and/or lower cost, an increase in integration density and/or an improvement in reliability of semiconductor devices may be advantageous. As the integration density of semiconductor devices increases, damage to the components of the semiconductor devices during the manufacturing process for semiconductor devices has a greater impact on the reliability and/or electrical characteristics of semiconductor memory devices. For example, during the manufacturing process for semiconductor devices, various treatment processes, for example, an etching process, a cleaning process, etc., may be performed on a given layer (for example, a metal-containing layer), during which the given layer may be damaged. There is continuing demand for a composition having an improved or appropriate etching rate and/or improved or excellent cleaning ability to perform a more effective metal-containing layer treatment process.

### SUMMARY

Provided are a composition having improved or excellent etching selectivity and/or improved or superior cleaning performance, a method of treating a metal-containing layer using the same, and a method of manufacturing a semiconductor device using the same.

Additional aspects will be set forth in part in the description which follows and, in part, will be apparent from the description, or may be learned by practice of the presented embodiments of the disclosure.

According to an aspect of the disclosure, a composition includes an oxidizer, an ammonium-based buffer and an etching controller, wherein the etching controller includes a compound represented by Formula 1:

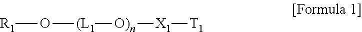

wherein, in Formula 1, R₁ may be a saturated or unsaturated aliphatic terminal group having 1 to 50 carbon atoms, L₁ may be a saturated or unsaturated aliphatic linking group having 1 to 10 carbon atoms, n may be an integer from 1 to 30, *—X₁-T₁ may be *—C(R₂)(R₃)—C(═O)—O-T₁ or *—S(═O)₂—O-T₁, R₂ and R₃ may each independently be hydrogen or a C₁-C₁₀ alkyl group, T₁ may be hydrogen, an alkali metal, or an ammonium group, * is a bonding site with a neighboring atom, and at least one hydrogen in R₁, L₁ and the C₁-C₁₀ alkyl group may optionally be substituted with a C₁-C₃₀ alkyl group, a C₂-C₃₀ alkenyl group, a C₃-C₃₀ carbocyclic group, a C₁-C₃₀ heterocyclic group, or a combination thereof.

According to another aspect of the disclosure, a method of treating a metal-containing layer includes preparing a substrate on which the metal-containing layer is provided; and contacting the metal-containing layer with the composition.

A metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or a combination thereof.

Due to the contacting of the metal-containing layer with the composition, at least a portion of the metal-containing layer may be etched and/or cleaned.

The metal-containing layer may include a first region and a second region, and a second etching rate at which the composition etches the second region may be greater than a first etching rate at which the composition etches the first region.

The first region may include at least one of cobalt or copper, and the second region may include titanium nitride.

Due to the contacting of the metal-containing layer and the composition, residues on the surface of the metal-containing layer are removed and thus, at least a portion of the metal-containing layer is cleaned.

The residues may include an etching gas residue, a polymer residue, a metal-containing residue, or any combination thereof.

According to another aspect of the disclosure, a method of manufacturing a semiconductor device includes preparing a substrate on which a metal-containing layer is provided, contacting the metal-containing layer with the composition, and performing a subsequent manufacturing process.

### BRIEF DESCRIPTION OF THE DRAWINGS

The other aspects, features, and advantages of certain embodiments of the disclosure will be more apparent from the following description taken in conjunction with the accompanying drawings, in which:

FIG. 1 shows a process flow diagram of least one embodiment of a method of manufacturing a semiconductor device;

FIGS. 2 and 3 are schematic drawings illustrating at least one embodiment of a method of treating a metal-containing layer; and

FIGS. 4A to 4J are cross-sectional views illustrating an embodiment of a trench and via hole pattern formation process for bit line electrode formation.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. When referring to “C to D”, this means C inclusive to D inclusive unless otherwise specified.

### Metal-Containing Layer

A metal included in the metal-containing layer may be an alkali metal (for example, sodium (Na), potassium (K), rubidium (Rb), cesium (Cs), etc.), an alkaline earth metal (for example, beryllium (Be), magnesium (Mg), calcium (Ca), strontium (Sr), barium (Ba), etc.), a lanthanide metal (for example, lanthanum (La), europium (Eu), terbium (Tb), ytterbium (Yb), etc.), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fc), ruthenium (Ru), osmium (Os), cobalt (Co), rhodium (Rh), nickel (Ni), copper (Cu), silver (Ag), zinc (Zn), etc.), a post-transition metal (for example aluminum (Al), gallium (Ga), indium (In), thallium (Tl), tin (Sn), bismuth (Bi), etc.), and/or a combination thereof.

For example, according to at least one embodiment, a metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), and/or a combination thereof.

For example, the metal-containing layer may include aluminum (Al), titanium (Ti), lanthanum (La), cobalt (Co), copper (Cu), and/or a combination thereof.

In some embodiments, the metal-containing layer may include titanium and/or cobalt.

In some embodiments, the metal-containing layer may include titanium and/or copper.

In at least some embodiments, the metal-containing layer may include a metal, a metal nitride, a metal oxide, a metal oxynitride and/or a combination thereof. According to at least one embodiment, each of the metal, the metal of the metal nitride, the metal of the metal oxide, and the metal of the metal oxynitride may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), and/or a combination thereof.

For example, in some embodiments, the metal-containing layer may include a metal nitride; and the metal included in the metal nitride may include indium, titanium, aluminum, lanthanum, scandium, gallium, zinc, hafnium, and/or a combination thereof.

For example, the metal-containing layer may include titanium nitride. The titanium nitride may further include indium, aluminum, lanthanum, scandium, gallium, hafnium, zinc, tungsten, and/or a combination thereof. In some embodiments, the metal-containing layer may include titanium nitride (TiN), titanium nitride further including aluminum (for example, titanium/aluminum nitride or TiAlN), titanium nitride further including lanthanum (for example, TiLaN), etc.

In some embodiments, the metal-containing layer may include a metal oxide. The metal included in the metal oxide may include titanium, aluminum, lanthanum, scandium, gallium, hafnium, and/or a combination thereof. For example, the metal-containing layer may include aluminum oxide (for example, Al₂O₃), indium gallium zinc oxide (IGZO), etc.

In some embodiments, the metal-containing layer may include the metal nitride and the metal oxide.

In some embodiments, the metal-containing layer may further include, in addition to the metal, a metalloid (for example, boron (B), silicon (Si), germanium (Ge), arsenic (As), antimony (Sb), tellurium (Te), etc.), a non-metal (for example, nitrogen (N), phosphorus (P), oxygen (O), sulfur(S), selenium (Se), etc.), and/or a combination thereof.

For example, the metal-containing layer may further include, e.g., silicon oxide.

The metal-containing layer may have a single-layer structure including one or more types of materials, a multi-layer structure, and/or three-dimensional pattern structure including different materials.

According to at least one embodiment, the metal-containing layer includes a first region and a second region, and a second etching rate at which the composition etches the second region may be greater than a first etching rate at which the composition etches the first region. During a treatment process for the metal-containing layer (for example, an etching process, a cleaning process, etc.), at least a portion of the first region and at least a portion of the second region may come into contact with the composition, and since the second etching rate is greater than the first etching rate, the second region may be etched faster than the first region. According to at least one embodiment, the compositions of the first region and the second region may be selected based etch selectivity with regards to the composition (described below in further detail), such that the first etching rate may be zero (0) and/or the first region may not be etched and/or such that the first etching rate is negligible compared to and/or slower than the second etching rate. In at least some embodiments, the composition of the first and second regions may be different.

For example, the first region may include a metal, a metal oxide (for example, aluminum oxide), silicon oxide, and/or a combination thereof.

According to at least one embodiment, the first region may include at least one of cobalt and/or copper.

In some embodiments, the second region may include a metal nitride.

In some embodiments, the second region may include i) titanium nitride (TiN), ii) titanium nitride further including indium, aluminum, lanthanum, scandium, gallium, zinc, hafnium, and/or a combination thereof (for example, TiAlN), and/or iii) a combination thereof.

In some embodiments, each of the first region and the second region may each include i) titanium nitride, ii) titanium nitride further including indium, aluminum, lanthanum, scandium, gallium, zinc, hafnium, and/or a combination thereof, and/or iii) a combination thereof.

In some embodiments, the first region may include at least one of cobalt and/or copper and the second region may not include cobalt or copper.

In some embodiments, the first region may include at least one of cobalt and copper, and the second region may include i) titanium nitride (TiN), ii) titanium nitride further including indium, aluminum, lanthanum, scandium, gallium, zinc, hafnium, and/or a combination thereof (for example, TiAlN), and/or iii) a combination thereof.

In some embodiments, the first region may include at least one of cobalt and copper, and the second region may include titanium nitride (TiN), titanium nitride further including aluminum (TiAlN), and/or a combination thereof.

In some embodiments, the first region may include at least one of a cobalt layer and/or a copper layer, and the second region may include at least one of a titanium nitride layer (TiN layer), a titanium nitride layer further including aluminum (for example, a titanium/aluminum nitride layer or TiAlN layer), and/or a combination thereof.

In some embodiments, the first region may be a cobalt layer, a copper layer, and/or a combination thereof, and the second region may be a titanium nitride layer (TiN layer) and/or a titanium nitride layer further including aluminum (for example, a titanium/aluminum nitride layer or TiAlN layer).

The wording “a layer is etched” as used herein refers to removing of at least some of a material constituting the layer.

### Composition

The composition may include an oxidizer, an ammonium-based buffer, and an etching controller.

The composition may be used in various treatment processes for the metal-containing layer described herein, for example, an etching process, a cleaning process, etc.

In at least some embodiments, the composition may further include water.

According to at least one embodiment, the composition may not include an abrasive. The absence of an abrasive may reduce and/or prevent damage to and/or contaminants on the metal-containing layer. For example, scratches resulting during the removal of an abrasive may be prevented due to the absence of an abrasive.

### Oxidizer

The oxidizer may etch at least a portion of the metal-containing layer by oxidizing at least a portion of the metal in the metal-containing layer to form a water-soluble complex, and may include, for example, at least one of hydrogen peroxide, nitric acid, and/or ammonium sulfate.

According to at least one embodiment, the oxidizer may include hydrogen peroxide.

In some embodiments, the oxidizer may be hydrogen peroxide.

The amount (e.g., by weight) of the oxidizer may be, for example, about 0.1 wt % to about 50 wt %, about 1 wt % to about 50 wt %, about 10 wt % to about 50 wt %, about 20 wt % to about 50 wt %, about 0.1 wt % to about 40 wt %, about 1 wt % to about 40 wt %, about 10 wt % to about 40 wt %, about 20 wt % to about 40 wt %, about 0.1 wt % to about 30 wt %, about 1 wt % to about 30 wt %, about 10 wt % to about 30 wt %, and/or about 20 wt % to about 30 wt %, based on 100 wt % of the composition.

### Ammonium-Based Buffer

The ammonium-based buffer is configured to maintain the concentration of anions generated from the oxidizer at a relatively high level, and to contribute to the stabilization of a water-soluble complex generated when the anions oxidize at least a portion of the metal of the metal-containing layer. Using such an ammonium-based buffer allows for effective etching of at least a portion of the metal-containing layer.

The ammonium-based buffer may include an ammonium group.

According to at least one embodiment, the ammonium-based buffer may include an ammonium group represented by N(A₁₁)(A₁₂)(A₁₃)(A₁₄), wherein A₁₁ to A₁₄ may each independently be hydrogen, a C₁-C₃₀ alkyl group, a C₂-C₃₀ alkenyl group, a C₃-C₃₀ carbocyclic group, and/or a C₁-C₃₀ heterocyclic group.

For example, A₁₁ to A₁₄ may each independently be hydrogen or a C₁-C₁₀ alkyl group.

In some embodiments, the ammonium-based buffer may include phosphate.

In some embodiments, the ammonium-based buffer may include a compound represented by Formula 11-1, a compound represented by Formula 11-2, and/or a combination thereof:

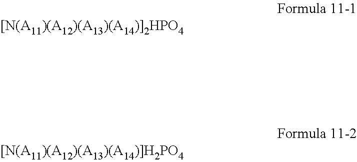

The description of each of A₁₁ to A₁₄ in Formulae 11-1 and 11-2 is as provided herein.

In some embodiments, the ammonium-based buffer may include at least one of diammonium monohydrogen phosphate ((NH₄)₂HPO₄), ammonium dihydrogen phosphate ((NH₄)H₂PO₄), bis(tetramethylammonium)monohydrogen phosphate ([N(CH₃)₄]₂HPO₄), and tetramethylammonium dihydrogen phosphate ([N(CH₃)₄]H₂PO₄).

The amount (e.g., weight) of the ammonium-based buffer may be, for example, about 0.01 wt % to about 10 wt %, about 0.05 wt % to about 10 wt %, about 0.1 wt % to about 10 wt %, about 0.01 wt % to about 5 wt %, about 0.05 wt % to about 5 wt %, about 0.1 wt % to about 5 wt %, about 0.01 wt % to about 1 wt %, about 0.05 wt % to about 1 wt %, and/or about 0.1 wt % to about 1 wt %, based on 100 wt % of the composition.

### Etching Controller

The etching controller is selected to interact with various metal atoms in the metal-containing layer (which may also be referred to as the target layer) to control, e.g., the etching rate, the etching evenness, etc. In addition, the etching controller may remove residues generated during a metal-containing layer formation process and/or a metal-containing layer patterning process.

The etching controller may include a compound represented by Formula 1:

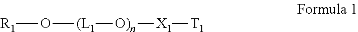

wherein, in Formula 1,
R₁ represents a saturated or unsaturated aliphatic terminal group having 1 to 50 carbon atoms,
L₁ represents a saturated or unsaturated aliphatic linking group having 1 to 10 carbon atoms,
n represents an integer from 1 to 30,
a group represented by *—X₁-T₁ may be *—C(R₂)(R₃)—C(═O)—O-T₁ or *—S(═O)₂—O-T₁,
R₂ and R₃ each independently represent a hydrogen or a C₁-C₁₀ alkyl group,
T₁ represents hydrogen, an alkali metal, or an ammonium group,
* is a bonding site with a neighboring atom, and
at least one hydrogen in R₁, L₁ and the C₁-C₁₀ alkyl group may optionally be substituted with a C₁-C₃₀ alkyl group, a C₂-C₃₀ alkenyl group, a C₃-C₃₀ carbocyclic group, a C₁-C₃₀ heterocyclic group, and/or a combination thereof.

According to at least one embodiment, R₁ in Formula 1 may be a saturated or unsaturated aliphatic terminal group having 4 to 40 carbon atoms, a saturated or unsaturated aliphatic terminal group having 4 to 30 carbon atoms, a saturated or unsaturated aliphatic terminal group having 10 to 40 carbon atoms, a saturated or unsaturated aliphatic terminal group having 10 to 30 carbon atoms, and/or a saturated or unsaturated aliphatic terminal group having 10 to 20 carbon atoms.

In some embodiments, L₁ in Formula 1 may be a saturated aliphatic linking group having 1 to 10 carbon atoms, a saturated aliphatic linking group having 2 to 10 carbon atoms, a saturated aliphatic linking group having 1 to 5 carbon atoms, and/or a saturated aliphatic linking group having 2 to 5 carbon atoms.

In some embodiments, n in Formula 1 may be an integer of 1 to 10, 1 to 5, 2 to 10, and/or 2 to 5.

In some embodiments, T₁ in Formula 1 may be hydrogen, Na, K, and/or N(A₁)(A₂)(A₃)(A₄), and A₁ to A₄ in Formula 1 may each independently be hydrogen, a C₁-C₃₀ alkyl group, a C₂-C₃₀ alkenyl group, a C₃-C₃₀ carbocyclic group, or a C₁-C₃₀ heterocyclic group. For example, A₁ to A₄ may each independently be hydrogen or a C₁-C₁₀ alkyl group.

In some embodiments, the etching controller may include a compound represented by Formula 1-1, a compound represented by Formula 1-2, and/or a combination thereof:

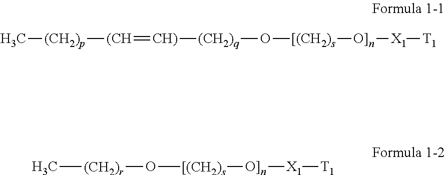

wherein, in Formulae 1-1 and 1-2,
p represents an integer from 0 to 10,
q represents an integer from 1 to 15 (and/or an integer from 1 to 11),
r represents an integer from 3 to 25, or 5 to 15, and
s and n each independently represent an integer from 2 to 10 (and/or an integer from 2 to 5).

In some embodiments, the etching controller may include at least one of Compounds 1 to 3:

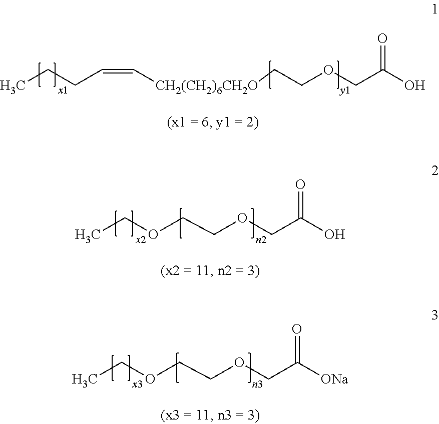

In some embodiments, the amount of the etching controller may in the range of about 0.001 wt % to about 10 wt %, about 0.01 wt % to about 10 wt %, about 0.1 wt % to about 10 wt %, about 0.001 wt % to about 5 wt %, about 0.01 wt % to about 5 wt %, about 0.1 wt % to about 5 wt %, about 0.001 wt % to about 1 wt %, about 0.01 wt % to about 1 wt %, and/or about 0.1 wt % to about 1 wt %, based on 100 wt % of the composition.

The group represented by *—X₁-T₁ in Formula 1 is a hydrophilic group that is configured to bond with a metal of the metal-containing layer, thereby binding the compound represented by Formula 1 to the metal-containing layer; R₁ in Formula 1 functions to provide a hydrophobic protective layer on the surface of the metal-containing layer; and the group represented by *-(L₁-O)ₙ—*′ in Formula 1 functions to assist in the dispersity of the compound represented by Formula 1. Therefore, by using a composition including the compound represented by Formula 1 as an etching controller, the etching rate may be selectively controlled according to the metal of the metal-containing layer, and simultaneously, residues generated during a metal-containing layer formation process and/or a metal-containing layer patterning process may be effectively removed.

The composition as described above may have a pH of about 1.0 to about 10.0, about 3.0 to about 10.0, about 5.0 to about 10.0, about 7.0 to about 10.0, about 3.0 to about 8.0, about 5.0 to about 8.0, and/or about 7.0 to about 8.0. Since the composition has such ranges of pH, the interaction between the etching controller and the metal atoms in the metal-containing layer as described below may occur more smoothly and may be adjusted based on the composition of the metal-containing layer.

According to at least one embodiment, the composition may be used in a treatment process for a metal-containing layer, for example, an etching process, a cleaning process, etc. for the metal-containing layer.

Alternatively, the composition may also be used as an etching byproduct remover, a post-etch process byproduct remover, an ashing process byproduct remover, a cleaning composition, a photoresist (PR) remover, an etching composition for packaging process, a cleaner for packaging process, a wafer adhesive material remover, an etchant, a post-etch residue stripper, an ash residue cleaner, a photoresist residue stripper, a post-chemical mechanical polishing (CMP) cleaner, and/or the like.

### Metal-Containing Layer Treatment Method and Semiconductor Device Manufacturing Method

A metal-containing layer may be effectively treated by using the composition described above.

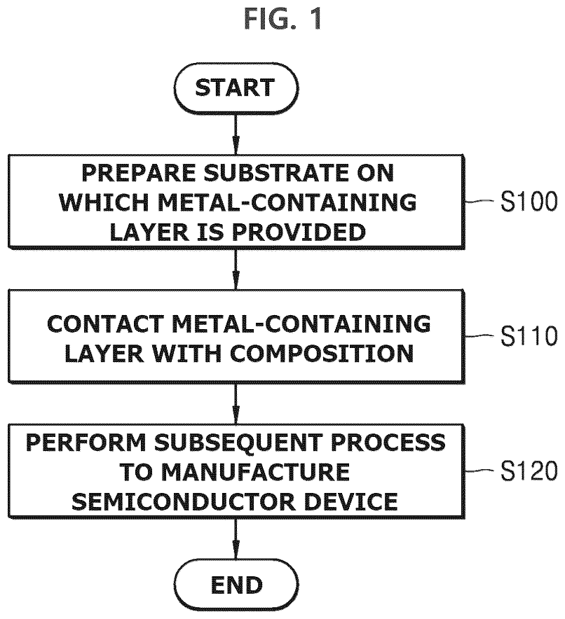

Referring to FIG. 1, at least one embodiment of the method of treating a metal-containing layer may include: preparing a substrate on which a metal-containing layer is provided S100; and contacting the metal-containing layer with a composition as described herein S110.

The metal-containing layer is as described herein.

For example, metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), and/or a combination thereof.

In some embodiments, the metal-containing layer may include a metal, a metal nitride, a metal oxide, a metal oxynitride, and/or a combination thereof.

In some embodiments, the metal-containing layer may include a metal, a metal nitride, a metal oxide, a metal oxynitride, and/or a combination thereof, and each of the metal, the metal of the metal nitride, the metal of the metal oxide, and the metal of the metal oxynitride may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), and/or a combination thereof.

In some embodiments, the metal-containing layer may include titanium nitride.

In some embodiments, the metal-containing layer may include at least one of cobalt and/or copper.

According to at least one embodiment, due to the contacting of the metal-containing layer with the composition, at least a portion of the metal-containing layer (e.g., a second region) may be etched and cleaned.

Regarding the composition, i) the oxidizer is configured to oxidize at least a portion of the metal of the metal-containing layer to form a water-soluble complex, thereby etching at least a portion of a metal-containing layer, ii) the ammonium-based buffer is configured to maintain the concentration of anions generated from the oxidizer and to effectively etch at least a portion of the metal-containing layer by stabilizing the water-soluble complex generated when the anions oxidize at least a portion of the metal of the metal-containing layer, and iii) the etching controller including the compound represented by Formula 1 is configured to effectively bind to a metal of the metal-containing layer due to a group represented by *—X₁-T₁, provide a hydrophobic protective layer on the surface of the metal-containing layer by R₁, and have excellent dispersibility due to a group represented by *-(L₁-O)ₙ—*′, wherein the etching controller may selectively control the etching rate depending on the metal of the metal-containing layer and at the same time, may effectively remove residues generated during a metal-containing layer formation process and/or a metal-containing layer patterning process. Therefore, the composition as described above may be usefully used in various treatment processes for the metal-containing layer.

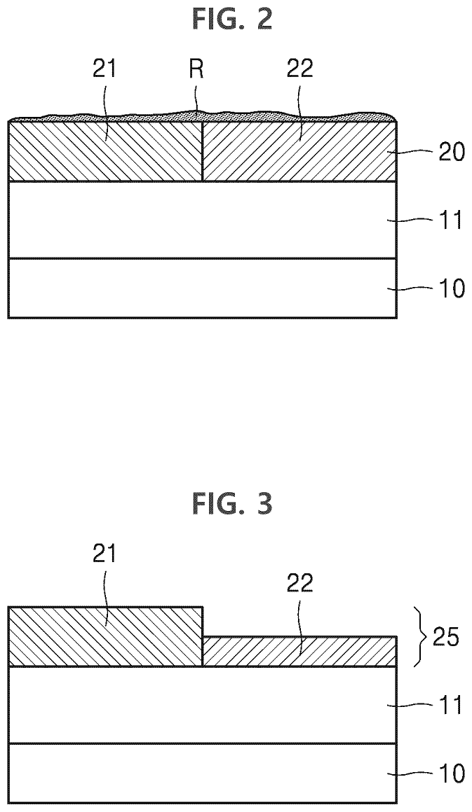

FIGS. 2 and 3 are schematic drawings illustrating at least one embodiment of a method of treating a metal-containing layer.

Referring to FIG. 2, a substrate 10, on which a metal-containing layer 20 is provided, is provided. An interlayer 11 may be placed between the substrate 10 and the metal-containing layer 20. In at least some embodiments, the interlayer 11 may be configured to protect the substate 10 during an etching processes. Although not shown in FIG. 2, circuitry elements (for example, transistor gates, metal lines, impurity regions, semiconductor layers) may be arranged within the substrate 10, on the substrate 10, and/or between the substrate 10 and the interlayer 11. According to at least one embodiment, the metal-containing layer 20 may be directly disposed on the substrate 10 and the interlayer 11 may be omitted.

The metal-containing layer 20 may include a first region 21 and a second region 22. The first region 21 and the second region 22 may be arranged spaced apart from each other or may be arranged such that at least some portion thereof are in contact with each other, and the metal-containing layer 20 may have various three-dimensional patterns. The second etching rate at which the composition etches the second region 22 may be greater than the first etching rate at which the composition etches the first region 21. For example, the first etching rate may be 0, and the first region 21 may not be etched.

Referring to FIG. 3, the composition may be used to etch the metal-containing layer 20 to etch at least a portion of the second region 22, thereby forming a metal-containing layer pattern 25. The etching process may be performed by contacting at least a portion of the first region 21 and at least a portion of the second region 22 with the composition.

The composition may etch only at least a portion of the second region 22 without etching the first region 21. Alternatively, the composition may etch each of a smaller portion of the first region 21 and a larger portion of the second region 22. Referring to FIG. 3, the metal-containing layer pattern 25 formed after etching includes at least a portion of the second region 22, but if necessary, various modifications are possible, such as the etching process being performed so that the second region 22 of the metal-containing layer pattern 25 is completely removed.

According to at least one embodiment, the first region 21 may include at least one of cobalt and/or copper.

According to some embodiments, the second region 22 may include a metal nitride (for example, titanium nitride).

According to some embodiments, the second region 22 may include i) titanium nitride (TiN), ii) titanium nitride further including indium, aluminum, lanthanum, scandium, gallium, zinc, hafnium, and/or a combination thereof (for example, TiAlN), and/or iii) a combination thereof.

In some embodiments, each of the first region 21 and the second region 22 may include i) titanium nitride, ii) titanium nitride further including indium, aluminum, lanthanum, scandium, gallium, zinc, hafnium, and/or a combination thereof, and/or iii) a combination thereof.

In some embodiments, the first region 21 may include at least one of cobalt and copper, and the second region 22 may not include cobalt and copper.

In some embodiments, the first region 21 may include at least one of cobalt and copper, and the second region 22 may include i) titanium nitride (TiN), ii) titanium nitride further including indium, aluminum, lanthanum, scandium, gallium, zinc, hafnium, and/or a combination thereof (for example, TiAlN), or iii) a combination thereof.

In some embodiments, the first region 21 may include at least one of cobalt and copper, and the second region 22 may include titanium nitride (TiN), titanium nitride further including aluminum (TiAlN), and/or a combination thereof.

In some embodiments, the first region 21 may include at least one of a cobalt layer and a copper layer, and the second region 22 may include a titanium nitride layer (TiN layer), a titanium nitride layer further including aluminum (for example, a titanium/aluminum nitride layer or TiAlN layer), and/or a combination thereof.

In some embodiments, the first region 21 may be a cobalt layer, and the second region 22 may be a titanium nitride layer (TiN layer) or a titanium nitride layer further including aluminum (for example, a titanium/aluminum nitride layer or TiAlN layer).

In some embodiments, the first region 21 may be a copper layer, and the second region 22 may be a titanium nitride layer (TiN layer) or a titanium nitride layer further including aluminum (for example, a titanium/aluminum nitride layer or TiAlN layer).

In some embodiments, due to the contacting the metal-containing layer 20 and the composition, a residue R on the surface of the metal-containing layer 20 is removed, thereby cleaning at least a portion of the metal-containing layer 20, thereby forming the metal-containing layer pattern 25 in which the residue R does not remain, as in FIG. 3.

The residue R is a material that remains on the surface of the metal-containing layer 20 and/or the metal-containing layer pattern 25 as a by-product generated during the formation and/or patterning of the metal-containing layer 20 to cause an increase in electrical resistance and/or an electrical short between electrical wires. The residue R may be an etching residue generated as a result of etching, and may include, for example, an etching gas residue, a polymer residue, a metal-containing residue, and/or a combination thereof.

The etching gas residue may be a residue derived from an etching gas used for dry etching. The etching gas may be, for example, a fluorocarbon gas. For example, the etching gas may include CHF₃, C₂F₆, CF₄, C₄F₈, C₂HF₅, etc. The etching gas residue may include the etching gas itself and/or a reaction product thereof with any material that come into contact with the etching gas during an etching process using the etching gas.

The polymer residue may be a polymer derived from various organic materials included in a photoresist, a dielectric layer, a buffer layer, a diffusion barrier layer, etc. used in manufacturing and/or patterning the metal-containing layer 20. For example, the polymer residue may be a polymer including carbon, silicon, fluorine, and/or a combination thereof.

The metal-containing residue may be any residue including metal separated from the metal-containing layer during the production and/or patterning of the metal-containing layer 20.

Referring back to FIG. 1, a method of manufacturing a semiconductor device according to at least one embodiment may further include performing a subsequent process to manufacture a semiconductor device S120.

In at least some embodiments, the preparing a substrate on which the metal-containing layer is provided S100 and the contacting the metal-containing layer with the composition may be used in a trench and via hole pattern formation process for forming a bit line electrode in a method of manufacturing a semiconductor device.

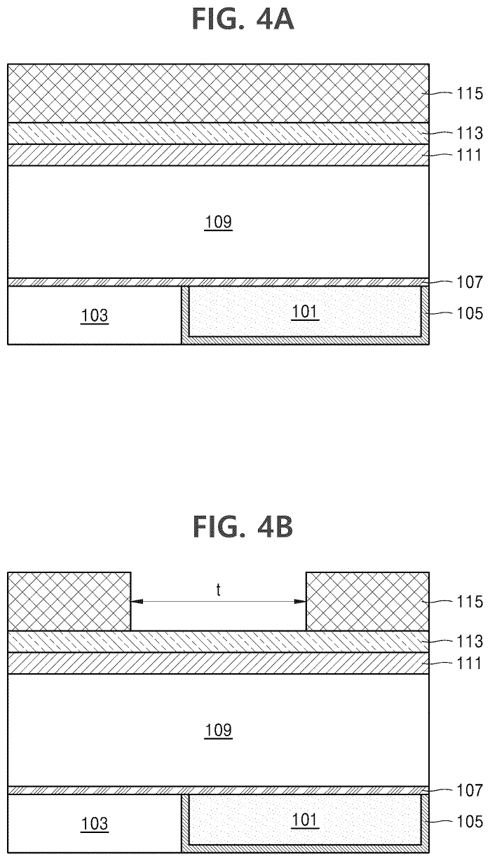

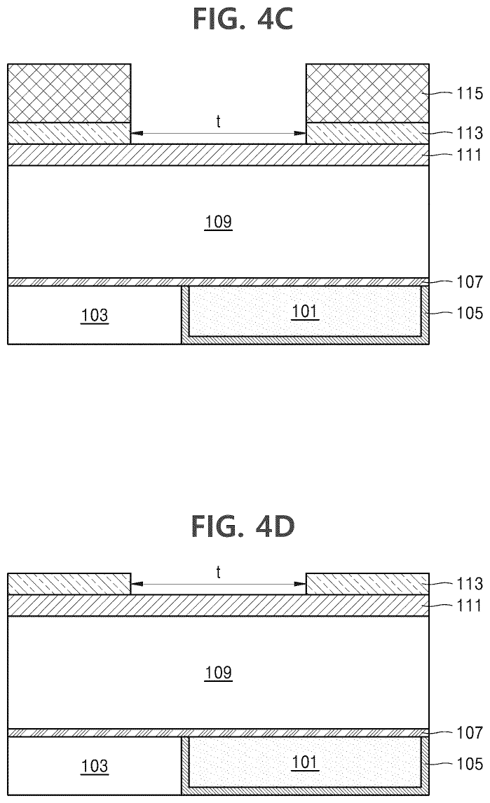

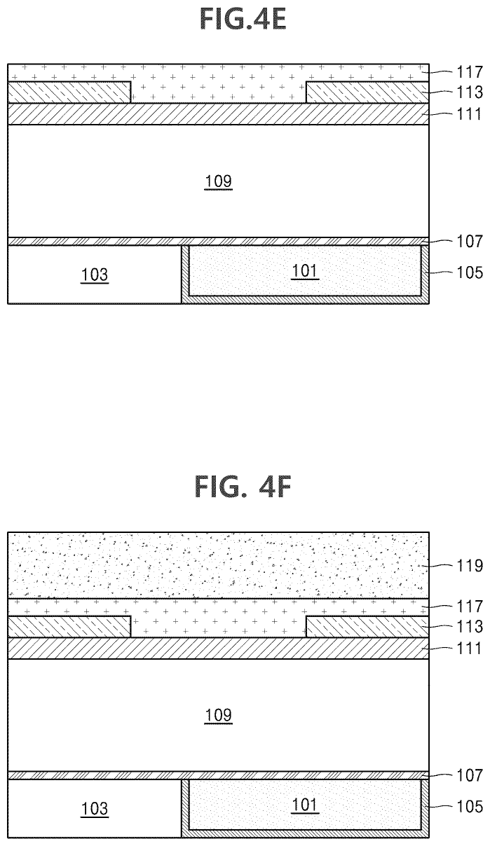

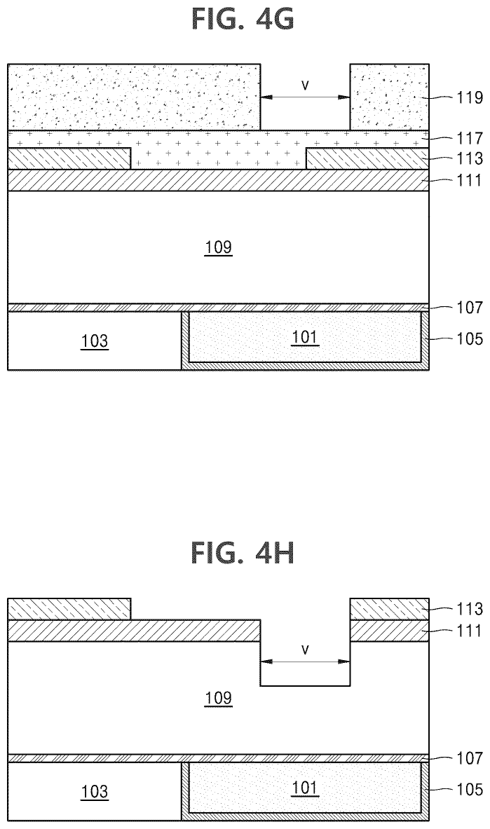

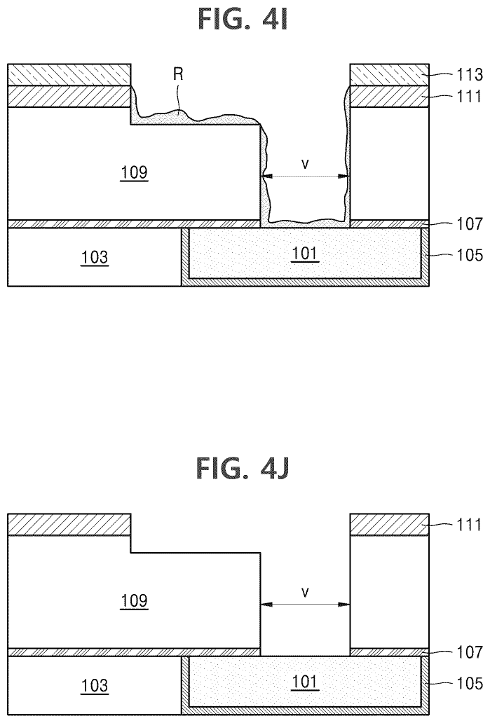

Hereinafter, with reference to FIGS. 4A to 4J, at least one embodiment of a trench and via hole pattern formation process for forming a bit line electrode using the composition will be described.

FIG. 4A illustrates a portion of a semiconductor substrate (transistors, etc. not shown) including a first dielectric layer 103 and a metal layer 101. The metal layer 101 may include, for example, at least one of copper and cobalt. A first diffusion barrier layer 105 may be placed between the first dielectric layer 103 and the metal layer 101. The first diffusion barrier layer 105 may include, for example, tantalum, titanium, tungsten, tantalum nitride, titanium nitride, tungsten nitride, and/or a combination thereof.

A second diffusion barrier layer 107 may be arranged on the first dielectric layer 103 and the metal layer 101 of FIG. 4A. The second diffusion barrier layer 107 may include, for example, silicon nitride or nitrogen-doped silicon carbide.

A second dielectric layer 109 may be placed on the second diffusion barrier layer 107 of FIG. 4A. The second dielectric layer 109 may include, for example, an ultra-low K (ULK) dielectric.

A buffer layer 111 which is mechanically robust may be placed on the second dielectric layer 109 of FIG. 4A to prevent damage to the second dielectric layer 109 when depositing a hard mask layer 113. The buffer layer 111 may include, for example, tetraethyl orthosilicate (TEOS), carbon-doped silicon oxide (SiCOH), etc.

The hard mask layer 113 may be placed on the buffer layer 111 of FIG. 4A. The hard mask layer 113 may include i) titanium nitride (TiN), ii) titanium nitride further including indium, aluminum, lanthanum, scandium, gallium, zinc, hafnium, and/or a combination thereof (for example, TiAlN), and/or iii) a combination thereof. For example, the hard mask layer 113 may include TiN.

A first photoresist 115 may be placed on the hard mask layer 113 of FIG. 4A.

Next, the first photoresist 115 is patterned to form a pattern of the first photoresist 115 having a first opening having a width t as illustrated in FIG. 4B, and then the hard mask layer 113 is etched according to the pattern of the first photoresist 115 to open a portion of the buffer layer 111 as illustrated in FIG. 4C, and then the pattern of the first photoresist 115 is removed by using, for example, ashing as illustrated in FIG. 4D to form an exposed pattern of the hard mask layer 113.

Next, as shown in FIG. 4E, a filler layer 117 is formed to cover the hard mask layer 113 pattern, thereby filling the opening of the pattern of the hard mask layer 113. The filler layer 117 may include, for example, hydrogen silsesquioxane (HSQ), methyl silsesquioxane (MSQ), and/or the like.

Thereafter, as shown in FIG. 4F, a second photoresist 119 is formed on the filler layer 117, and then the second photoresist 119 is patterned to form a pattern of the second photoresist 119 having a second opening having a width v, as shown in FIG. 4G, and the filler layer 117, a portion of the pattern of the hard mask layer 113, a portion of the buffer layer 111, and a portion of the second dielectric layer 109, which are located under the pattern of the second photoresist 119, are etched by using, for example, reactive ion etching (RIE), etc., to form a portion of a via hole, as shown in FIG. 4H, and then the pattern of the second photoresist 119 and the filler layer 117 are removed.

Next, as illustrated in FIG. 4I, according to the pattern of the hard mask layer 113, the buffer layer 111, the second dielectric layer 109, and the second diffusion barrier layer 107 are etched by using, for example, a dry etching process, until the via hole reaches the metal layer 101, thereby forming a trench and via hole pattern. The etching gas used in the dry etching process may be, for example, fluorocarbon gas (for example, CHF₃, C₂F₆, CF₄, C₄F₈, C₂HF₅, etc.).

As a result of the dry etching, a large amount of residue R may exist on the inner wall of the trench and via hole pattern, as shown in FIG. 4I. The residue R may include an etching gas residue, a polymer residue, a metal-containing residue, and/or a combination thereof. The etching gas residue may include the etching gas itself and/or a reaction product thereof with any material (for example, material included in the buffer layer 111, the second dielectric layer 109, etc.) that come into contact with the etching gas during an etching process using the etching gas. The polymer residue may be a polymer derived from various organic materials included in the second photoresist 119, the second dielectric layer 109, the buffer layer 111, the second diffusion barrier layer 107, etc. For example, the polymer residue may be a polymer including carbon, silicon, fluorine, and/or a combination thereof. The metal-containing residue may be, for example, a residue including a metal included in the pattern of the hard mask layer 113.

The residue R illustrated in in FIG. 4I may decrease the reliability of the semiconductor device by unpredictably increasing the electrical resistance of the semiconductor device and/or by cause an electrical short of a bit line electrode to be formed later. Accordingly, the residue R needs to be removed. Meanwhile, to simplify the process, the residue R and the pattern of the hard mask layer 113 may be removed at the same time. In addition, the metal layer 101 should not be substantially damaged when the residue R and the pattern of the hard mask layer 113 are removed.

To this end, by applying the composition including an oxidizer, an ammonium-based buffer, and an etching controller as described above to the substrate of FIG. 4I on which the pattern of the hard mask layer 113 and a metal-containing layer including the metal layer 101 are disposed, i) the residue R generated on the inner wall of the trench and via hole pattern is removed, while ii) the pattern of the hard mask layer 113 is removed and iii) the metal layer 101 is substantially undamaged, thereby manufacturing the substrate of FIG. 4J. Although not intended to be limited by a specific theory, for example, the pattern of the hard mask layer 113 may be removed by an oxidizer and an ammonium-based buffer, while the residue R is removed by the etching controller and at the same time, the metal layer 101 is substantially not etched. Thereafter, a bit line electrode, etc. may be formed by filling the trench and via hole pattern of FIG. 4J with a metallic material, etc.

### Examples 1 to 3 and Comparative Examples A and B

Compositions of Examples 1 to 3 and Comparative Examples A and B were prepared by mixing 25 wt % of hydrogen peroxide as an oxidizer, 0.5 wt % of diammonium monohydrogen phosphate ((NH₄)₂HPO₄) as an ammonium-based buffer, and 0.2 wt % of the etching controllers. The remainder of each composition corresponds to water (deionized water).

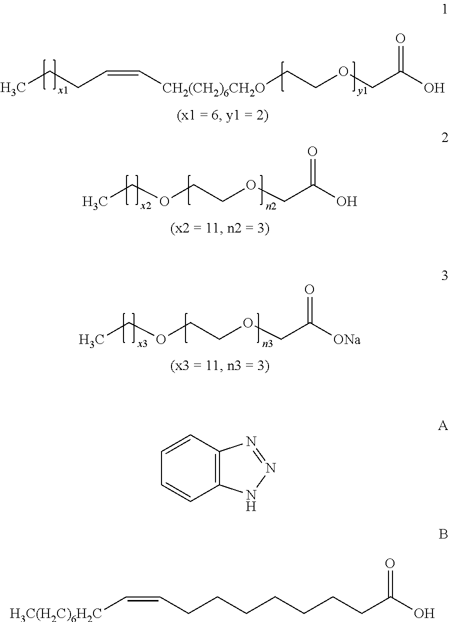

### Comparative Example C

A composition was prepared in the same manner as in Example 3, except that no ammonium-based buffer was used.

### Evaluation Example 1

A substrate on which a trench and via hole patterns for forming a bit line electrode was formed and a residue existed on the inner walls of the trench and via hole pattern, was immersed for 5 minutes in a dip type bath containing the composition (25° C.) of Example 1, and then subjected to a rinsing and drying process. The removal of the residue was evaluated. Results are summarized in Table 1. The substrate is a substrate having a trench and via hole pattern formed thereon as shown in FIG. 4I.

This test was repeated using each of the compositions of Examples 2 to 3 and Comparative Examples A to C. Results are summarized in Table 1.

TABLE 1

| | Ammonium-based | Etching | Whether most of the |
|---|---|---|---|
| | buffer | controller | residue was removed |
| Example 1 | (NH₄)₂HPO₄ | 1 | ◯ |
| Example 2 | (NH₄)₂HPO₄ | 2 | ◯ |
| Example 3 | (NH₄)₂HPO₄ | 3 | ◯ |
| Comparative | (NH₄)₂HPO₄ | A | X |
| Example | | | |
| A | | | |
| Comparative | (NH₄)₂HPO₄ | B | X |
| Example | | | |
| B | | | |
| Comparative | — | 3 | ◯ |
| Example | | | |
| C | | | |

◯: Most of the residue is removed
X: A significant amount of residue remains

From Table 1, it is confirmed that the compositions of Examples 1 to 3 and Comparative Example C remove most of the residues, whereas the compositions of Comparative Examples A and B leave a significant amount of residues unremoved, indicating that the compositions of Comparative Examples A and B had poor cleaning ability. Next, Evaluation Example 2 was performed on the compositions of Examples 1 to 3 and Comparative Example C.

### Evaluation Example 2

The composition of Example 1 was placed in each of three beakers and heated to 70° C., and then the titanium nitride (TiN), and copper and cobalt layers which were subjected to a plasma etching treatment were immersed in each beaker for 5 minutes, and then the thickness of each of the titanium nitride layer, the copper layer, and the cobalt layer was measured using an ellipsometer (M-2000, JA Woolam). The etching rate (Å/min) of the composition of Example 1 for the titanium nitride layer, the etching rate (Å/min) for the copper layer and the etching rate (Å/min) for the cobalt layer were evaluated. Next, the etching rate for the titanium nitride layer was divided by the etching rate for the copper layer to evaluate R(TiN/Cu), and the etching rate for the titanium nitride layer was divided by the etching rate for the cobalt layer to evaluate R(TiN/Co). Results were summarized in Table 2.

This test was repeated using each of the compositions of Example 2, Example 3, and Comparative Example C. Results are summarized in Table 2.

TABLE 2

| | | | Titanium | | | | |
|---|---|---|---|---|---|---|---|
| | | | nitride | Etching | Etching | | |
| | | | layer | rate for | rate for | | |
| | | | Etching | copper | cobalt | | |
| | Ammonium- | Etching | rate | layer | layer | | |
| | based buffer | controller | (Å/min) | (Å/min) | (Å/min) | R(TiN/Cu) | R(TiN/Co) |
| Example 1 | (NH₄)₂HPO₄ | 1 | 137 | 0.2 | 0.3 | 685 | 457 |
| Example 2 | (NH₄)₂HPO₄ | 2 | 135 | 0.4 | 0.6 | 338 | 225 |
| Example 3 | (NH₄)₂HPO₄ | 3 | 120 | 0.4 | 0.6 | 300 | 200 |
| Comparative | — | 3 | 95 | 0.5 | 0.7 | 190 | 136 |
| Example | | | | | | | |
| C | | | | | | | |

From Table 2, it can be confirmed that the compositions of Examples 1 to 3 implement a high etching selectivity between the titanium nitride layer and the copper layer and a high etching selectivity between the titanium nitride layer and the cobalt layer, compared to the composition of Comparative Example C.

From Table 1 and Table 2, it can be confirmed that the compositions of Examples 1 to 3, compared to the compositions of Comparative Examples A to C, implement a higher etching selectivity between the titanium nitride layer and the copper layer and a higher etching selectivity between the titanium nitride layer and the cobalt layer while showing improved or excellent removal performance for residues generated during a metal-containing layer formation process and/or a metal-containing layer patterning process.

The composition according to the present disclosure has improved or excellent etching selectivity and/or improved or excellent cleaning performance, and thus, can be more effectively used in various treatment processes for various metal-containing layers, for example, an etching process, a cleaning process, etc. Therefore, by treating a metal-containing layer using the composition, a higher-quality semiconductor device can be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition comprising:
an oxidizer;
an ammonium-based buffer; and
an etching controller,
wherein the etching controller comprises a compound represented by Formula 1 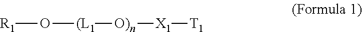
wherein, in Formula 1,
R₁ is a saturated or unsaturated aliphatic terminal group having 1 to 50 carbon atoms,
L₁ is a saturated or unsaturated aliphatic linking group having 1 to 10 carbon atoms,
n is an integer from 1 to 30,
*—X₁-T₁ is *—C(R₂)(R₃)—C(═O)—O-T₁ or *—S(═O)₂—O-T₁,
R₂ and R₃ are each independently hydrogen or a C₁-C₁₀ alkyl group,
T₁ is hydrogen, an alkali metal, or an ammonium group,
* is a bonding site with a neighboring atom, and
at least one hydrogen in R₁, L₁ and the C₁-C₁₀ alkyl group is optionally substituted with a C₁-C₃₀ alkyl group, a C₂-C₃₀ alkenyl group, a C₃-C₃₀ carbocyclic group, a C₁-C₃₀ heterocyclic group, or a combination thereof.

2. The composition of claim 1, wherein
the oxidizer comprises hydrogen peroxide.

3. The composition of claim 1, wherein
an amount of the oxidizer is about 0.1 wt % to about 50 wt %, based on 100 wt % of the composition.

4. The composition of claim 1, wherein
the ammonium-based buffer comprises an ammonium group represented by N(A₁₁)(A₁₂)(A₁₃)(A₁₄), and
A₁₁ to A₁₄ are each independently hydrogen, a C₁-C₃₀ alkyl group, a C₂-C₃₀ alkenyl group, a C₃-C₃₀ carbocyclic group, or a C₁-C₃₀ heterocyclic group.

5. The composition of claim 1, wherein
the ammonium-based buffer comprises phosphate.

6. The composition of claim 1, wherein
the ammonium-based buffer comprises a compound represented by Formula 11-1, a compound represented by Formula 11-2, or a combination thereof: 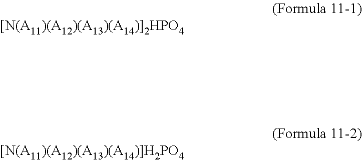
wherein, in Formulae 11-1 and 11-2, A₁₁ to A₁₄ are each independently hydrogen, a C₁-C₃₀ alkyl group, a C₂-C₃₀ alkenyl group, a C₃-C₃₀ carbocyclic group, or a C₁-C₃₀ heterocyclic group.

7. The composition of claim 1, wherein
the ammonium-based buffer comprises at least one of diammonium monohydrogen ((NH₄)₂HPO₄), ammonium dihydrogen phosphate ((NH₄)H₂PO₄), phosphate bis(tetramethylammonium)monohydrogen phosphate ([N(CH₃)₄]₂HPO₄), and tetramethylammonium dihydrogen phosphate ([N(CH₃)₄]H₂PO₄).

8. The composition of claim 1, wherein
an amount of the ammonium-based buffer is about 0.01 wt % to about 10 wt %, based on 100 wt % of the composition.

9. The composition of claim 1, wherein
R₁ is a saturated or unsaturated aliphatic terminal group having 4 to 40 carbon atoms,
L₁ is a saturated aliphatic linking group having 1 to 10 carbon atoms, and
n is an integer from 1 to 10.

10. The composition of claim 1, wherein
T₁ is hydrogen, Na, K, or N(A₁)(A₂)(A₃)(A₄), and
A₁ to A₄ are each independently hydrogen, a C₁-C₃₀ alkyl group, a C₂-C₃₀ alkenyl group, a C₃-C₃₀ carbocyclic group, or a C₁-C₃₀ heterocyclic group.

11. The composition of claim 1, wherein
the etching controller comprises a compound represented by Formula 1-1, a compound represented by Formula 1-2, or a combination thereof: 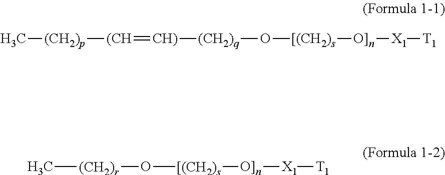
wherein, in Formulae 1-1 and 1-2,
p is an integer from 0 to 10,
q is an integer from 1 to 15,
r is an integer from 3 to 25,
s is an integer from 2 to 10, and
n is an integer from 2 to 10.

12. The composition of claim 1, wherein
an amount of the etching controller is about 0.001 wt % to about 10 wt %, based on 100 wt % of the composition.

13. A method of treating a metal-containing layer, comprising:
preparing a substrate on which the metal-containing layer is provided; and
contacting the metal-containing layer with the composition according to claim 1.

14. The method of claim 13, wherein
the metal-containing layer includes titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or a combination thereof.

15. The method of claim 13, wherein
the metal-containing layer includes a metal, a metal nitride, a metal oxide, a metal oxynitride, or a combination thereof, and
each of the metal, a metal of the metal nitride, a metal of the metal oxide, and a metal of the metal oxynitride comprises titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or a combination thereof.

16. The method of claim 13, wherein
at least a portion of the metal-containing layer is etched and cleaned due to the contacting of the metal-containing layer with the composition.

17. The method of claim 13, wherein
the metal-containing layer includes a first region and a second region, and
a second etching rate at which the composition etches the second region is greater than a first etching rate at which the composition etches the first region.

18. The method of claim 17, wherein
the first region includes at least one of cobalt or copper, and
the second region includes titanium nitride.

19. The method of claim 13, wherein
the contacting of the metal-containing layer with the composition includes removing residue on the metal-containing layer due to the contact, and
the residue comprises at least one of etching gas residue, polymer residue, or metal-containing residue.

20. A method of manufacturing a semiconductor device, comprising:
preparing a substrate on which a metal-containing layer is provided, and
contacting the metal-containing layer with the composition according to claim 1; and
performing a subsequent manufacturing process.
